(19) United States
(12) Patent Application Publication
(10) Pub. No.: US 2025/0359328 A1
(43) Pub. Date: Nov. 20, 2025

(54) SEMICONDUCTOR DEVICE INCLUDING A GATE CUTTING PATTERN

(71) Applicant: SAMSUNG ELECTRONICS CO., LTD., SUWON-SI (KR)

(72) Inventors: Minwoo KIM, Suwon-si (KR); Byungho MOON, Suwon-si (KR); Donghoon HWANG, Suwon-si (KR); Wonchang LEE, Suwon-si (KR); Jaeho JEON, Suwon-si (KR); Keetae KIM, Suwon-si (KR); Seongkwang KIM, Suwon-si (KR); Jina KIM, Suwon-si (KR); Hyunsoo KIM, Suwon-si (KR)

(21) Appl. No.: 19/073,900

(22) Filed: Mar. 7, 2025

(30) Foreign Application Priority Data
May 16, 2024 (KR) 10-2024-0064086

(51) Int. Cl. H10D 84/90

(52) U.S. Cl. CPC H10D 84/929; H10D 84/953

(57) ABSTRACT

A three-dimensional semiconductor device is provided. The three-dimensional semiconductor device may include a first active region on a substrate, the first active region including a lower channel pattern and lower source/drain patterns connected to the lower channel pattern, a second active region on the first active region, the second active region including an upper channel pattern and an upper source/drain pattern connected to the upper channel pattern, a gate electrode on the lower channel pattern and the upper channel pattern, and a gate cutting pattern penetrating the gate electrode, and the gate cutting pattern may have a middle width between an upper surface and a lower surface thereof that is less than an upper width of an upper portion of the gate cutting pattern and a lower width of a lower portion of the gate cutting pattern.

### CROSS-REFERENCE TO RELATED APPLICATIONS

This application claims priority under 35 U.S.C. § 119 to Korean Patent Application No.10-2024-0064086, filed on May 16, 2024, in the Korean Intellectual Property Office, the entire contents of which are hereby incorporated by reference.

### BACKGROUND

### 1. Technical Field

The inventive concept relates to a semiconductor device and a method of manufacturing the same, and more particularly, to a three-dimensional semiconductor device including a gate cutting pattern and a method of manufacturing the same.

### 2. Discussion of Related Art

A semiconductor device may include an integrated circuit having, for example, metal-oxide-semiconductor field effect transistors (MOSFET). The metal-oxide-semiconductor field effect transistor may be scaled-down with a reduction in a size and a design rule of the semiconductor device. As the MOSFET is scaled down, operational characteristics of the semiconductor device may be degraded.

### SUMMARY

An object of the inventive concept is to provide a three-dimensional semiconductor device with improved integration and electrical characteristics.

An object of the inventive concept is to provide a method of manufacturing a three-dimensional semiconductor device with improved integration and electrical characteristics.

Aspects of the inventive concept are not limited to the present description, and other aspects not mentioned will be clearly understood by those skilled in the art from the description below.

A three-dimensional semiconductor device according to some embodiments of the inventive concept may include a first active region on a substrate, the first active region including a lower channel pattern and lower source/drain patterns connected to the lower channel pattern, a second active region on the first active region, the second active region including an upper channel pattern and an upper source/drain pattern connected to the upper channel pattern, a gate electrode on the lower channel pattern and the upper channel pattern, and a gate cutting pattern penetrating the gate electrode, wherein the gate cutting pattern has a middle width between an upper surface and a lower surface thereof that is less than an upper width of an upper portion of the gate cutting pattern and a lower width of a lower portion of the gate cutting pattern.

A three-dimensional semiconductor device according to some embodiments of the inventive concept may include a first active region on a substrate, the first active region including a lower channel pattern and a lower source/drain pattern connected to the lower channel pattern, a second active region on the first active region, the second active region including an upper channel pattern and an upper source/drain pattern connected to the upper channel pattern, a gate electrode disposed on the lower channel pattern and the upper channel pattern and extending in a first direction, and a gate cutting pattern penetrating the gate electrode, wherein the gate cutting pattern includes a first portion adjacent to the second active region and a second portion disposed on the first portion and adjacent to the first active region, and each of the first portion and the second portion has a width that decreases toward a middle width of the gate cutting pattern.

A three-dimensional semiconductor device according to some embodiments of the inventive concept may include a first active region on a substrate, the first active region including a lower channel pattern and lower source/drain patterns connected to the lower channel pattern, a second active region on the first active region, the second active region including an upper channel pattern and an upper source/drain pattern connected to the upper channel pattern, a lower active contact connected to the lower source/drain pattern, an upper active contact connected to the upper source/drain pattern, a gate electrode disposed on the lower channel pattern and the upper channel pattern and extending in a first direction, a gate contact connected to the gate electrode, and a gate cutting pattern extending in a second direction crossing the first direction and penetrating the gate electrode, wherein the gate cutting pattern includes a first portion and a second portion below the first portion, and the gate cutting pattern has a middle width at an interface where the first portion and the second portion are in contact with each other that is less than an upper width of the second portion of the gate cutting pattern and a lower width of first portion of the gate cutting pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a conceptual diagram for explaining a logic cell of a semiconductor device according to a comparative example of the inventive concept.

FIG. 2 is a conceptual diagram for explaining a logic cell of a semiconductor device according to embodiments of the inventive concept.

FIG. 3 is a plan view for explaining a three-dimensional semiconductor device according to embodiments of the inventive concept.

FIGS. 4A to 4D are diagrams for explaining a three-dimensional semiconductor device according to embodiments of the inventive concept, and are cross-sectional views taken along lines A-A′, B-B′, C-C′, and D-D in FIG. 3.

FIGS. 5A to 5C are diagrams for explaining a gate cutting pattern of a three-dimensional semiconductor device according to embodiments of the inventive concept, and are enlarged views of region ‘M’ of FIG. 4C.

FIGS. 6A and 6B, FIGS. 7A to 7C, FIGS. 8A to 8D, FIGS. 9A to 9D, FIGS. 10A to 10D, and FIGS. 11A to 11D are diagrams for explaining a method of manufacturing a three-dimensional semiconductor device according to embodiments of the inventive concept, FIGS. 6A, 7A, 8A, 9A, 10A, and 11A are cross-sectional views taken along line A-A′ of FIG. 3, FIGS. 8B, 9B, 10B, and 11B are cross-sectional views taken along line B-B′ of FIG. 3, FIGS. 7B, 8C, 9C, and 10C, and FIG. 11C are cross-sectional views taken along line C-C′ of FIG. 3, and FIGS. 6B, 7C, 8D, 9D, 10D, and FIG. 11D are cross-sectional views taken along line D-D′ of FIG. 3.

### DETAILED DESCRIPTION

Hereinafter, embodiments of the inventive concept will be described with reference to the attached drawings. The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept. The same reference numerals may refer to the same elements throughout the specification. In the drawings, the thickness, the ratio, and the dimension of the elements may be exaggerated for effective description of the technical contents.

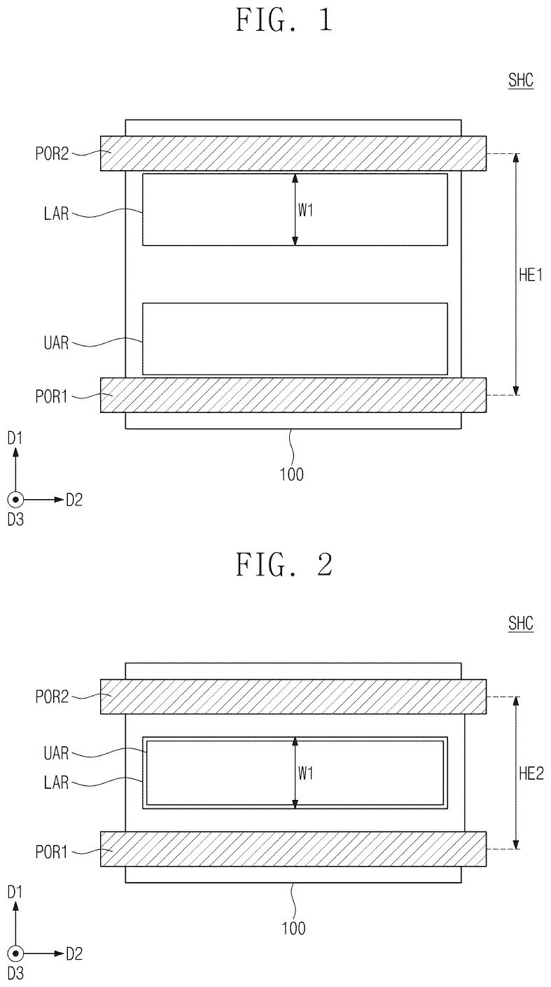

FIG. 1 is a conceptual diagram for explaining a logic cell of a semiconductor device according to a comparative example of the inventive concept.

Referring to FIG. 1, a single height cell SHC may be provided. In detail, a first power line POR1 and a second power line POR2 may be disposed on a substrate 100. A drain voltage VDD (or a power voltage) may be applied to one of the first or second power lines POR1 and POR2. A source voltage VSS (or a ground voltage) may be applied to the other of the first and second power lines POR1 and POR2. For example, the source voltage VSS may be applied to the first power line POR1, and the drain voltage VDD may be applied to the second power line POR2.

The single height cell SHC may be defined between the first power line POR1 and the second power line POR2. The single height cell SHC may include a lower active region LAR and an upper active region UAR. One of the lower active region LAR or the upper active region UAR may be a PMOSFET region. The other one of the lower active region LAR or upper active region UAR may be an NMOSFET region. For example, the lower active region LAR may be an NMOSFET region, and the upper active region UAR may be a PMOSFET region. That is, the single height cell SHC may have a CMOS structure disposed between the first power line POR1 and the second power line POR2.

The semiconductor device according to the comparative example of the inventive concept may be a two-dimensional device, and transistors in a front end of line (FEOL) layer may be arranged two-dimensionally. For example, the NMOSFET of the lower active region LAR and the PMOSFET of the upper active region UAR may be spaced apart from each other in a first direction D1.

Each of the lower active region LAR and the upper active region UAR may have a first width W1 in the first direction D1. A length of the single height cell SHC according to the comparative example of the inventive concept in the first direction D1 may be defined as a first height HE1. The first height HE1 may be substantially equal to a distance (e.g., a pitch) between the first power line POR1 and the second power line POR2.

The single height cell SHC may constitute a logic cell. In this specification, a logic cell may refer to a logic device (e.g., AND, OR, XOR, XNOR, inverter, etc.) that performs a specific function. That is, a logic cell may include transistors for configuring a logic device and wirings connecting the transistors to each other.

As the single height cell SHC according to the comparative example of the inventive concept may include a two-dimensional device, the lower active region LAR and upper active region UAR may not overlap each other vertically and may be spaced apart from each other in the first direction D1. Accordingly, the first height HE1 of the single height cell SHC may be defined to encompass both the lower and upper active regions LAR and UAR spaced apart from each other in the first direction D1. As a result, the area of the single height cell SHC according to the comparative example of the inventive concept may be relatively large.

FIG. 2 is a conceptual diagram for explaining a logic cell of a semiconductor device according to embodiments of the inventive concept.

Referring to FIG. 2, a single height cell SHC including a three-dimensional device may be provided. The single height cell SHC including a three-dimensional device may include a stacked transistor. In detail, a first power line POR1 and a second power line POR2 may be disposed on a substrate 100. The single height cell SHC may be defined between the first power line POR1 and the second power line POR2.

The single height cell SHC may include a lower active region LAR and an upper active region UAR. One of the lower active region LAR or the upper active region UAR may be a PMOSFET region, and the other one of the lower active region LAR or the upper active region UAR may be an NMOSFET region.

The semiconductor device according to embodiments of the inventive concept may be a three-dimensional device, and transistors of a FEOL layer may be vertically stacked. The lower active region LAR may be provided as a bottom tier on the substrate 100, and an upper active region UAR may be stacked on the lower active region LAR and may be provided as a top tier. For example, an NMOSFET in the lower active region LAR may be disposed on the substrate 100, and a PMOSFET in the upper active region UAR may be stacked on the NMOSFET. The lower active region LAR and the upper active region UAR may be spaced apart from each other in a vertical direction (e.g., a third direction D3).

Each of the lower active region LAR and the upper active region UAR may have a first width W1 in the first direction D1. A length of the single height cell SHC in the first direction D1 according to embodiments of the inventive concept may be defined as a second height HE2. The single height cell SHC according to embodiments of the inventive concept may include a three-dimensional device that may include a stacked transistor, and the lower active region LAR and the upper active region UAR may vertically overlap each other. Accordingly, the second height HE2 of the single height cell SHC may have a size that encompasses a first width W1. The second height HE2 of the single height cell SHC according to embodiments of the inventive concept may be smaller than the first height HE1 of the single height cell SHC of FIG. 1. That is, the area of a single height cell SHC according to embodiments of the inventive concept may be relatively small. Given a relatively small area of the single height cell SHC, integration of the single height cell SHC may be improved in a semiconductor device.

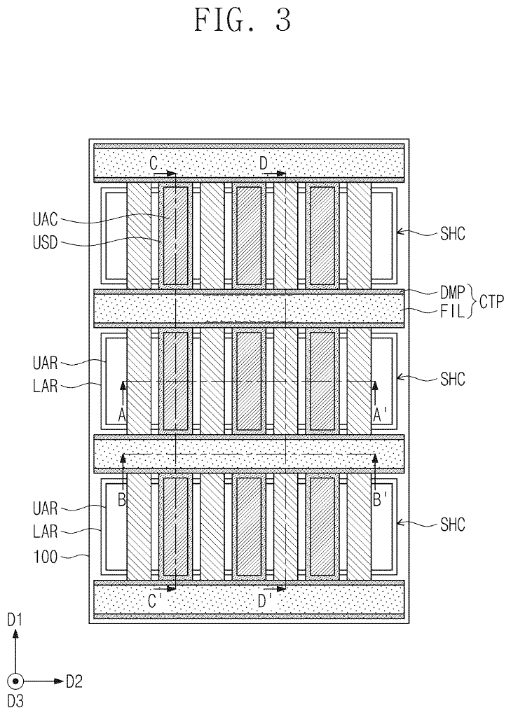

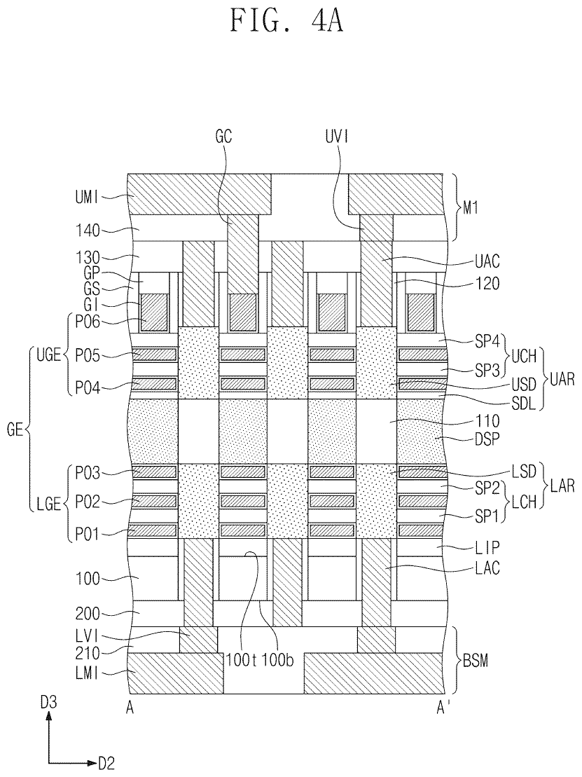

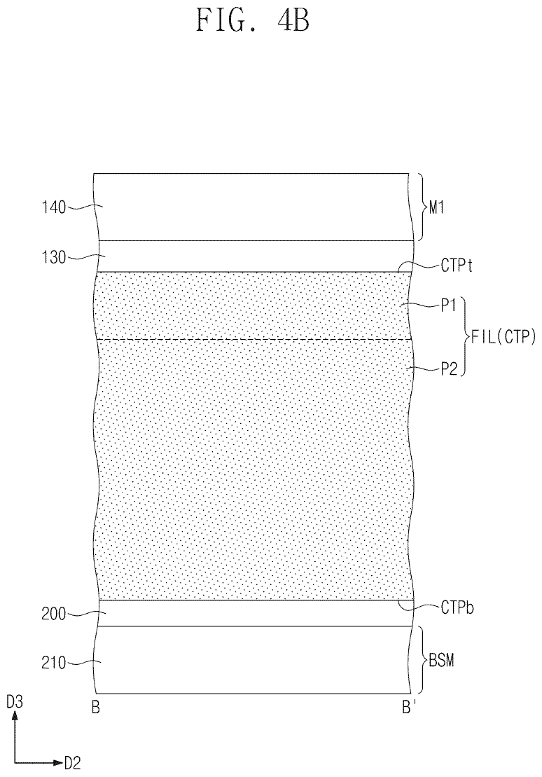

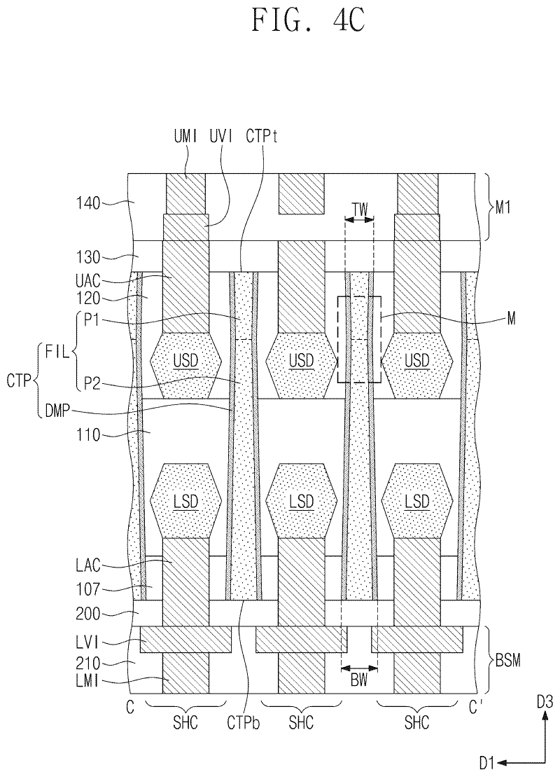

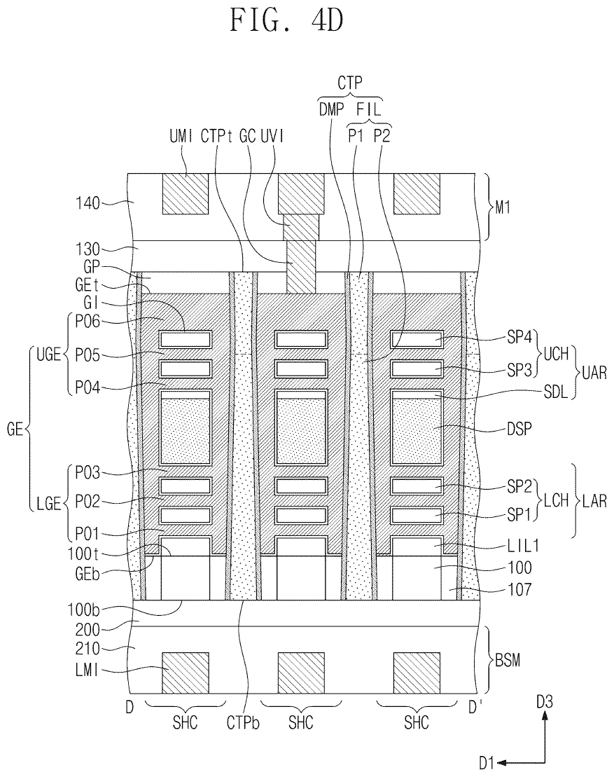

FIG. 3 is a plan view for explaining a three-dimensional semiconductor device according to embodiments of the inventive concept. FIGS. 4A to 4D are diagrams for explaining a three-dimensional semiconductor device according to embodiments of the inventive concept, and are cross-sectional views taken along lines A-A′, B-B′, C-C′, and D-D, respectively. The lines A-A′, B-B′, C-C′, and D-D are illustrated in FIG. 3.

Referring to FIG. 3 and FIGS. 4A to 4D, single height cells SHC may be disposed on a substrate 100. Each single height cell SHC may be a logic cell constituting a logic circuit. Each single height cell SHC may be a logic cell including the three-dimensional device described above with reference to FIG. 2. The single height cells SHC may be arranged in the first direction D1.

The substrate 100 may include a first surface 100t and a second surface 100b facing each other. The first surface 100t may be an upper surface (or a front surface) of the substrate 100. The second surface 100b may be a lower surface (or a back surface) of the substrate 100. For example, the substrate 100 may be an insulating substrate including a silicon-based insulating material (e.g., silicon oxide and/or silicon nitride). Alternatively, the substrate 100 may be a semiconductor substrate including silicon, germanium, silicon germanium, etc.

Each single height cell SHC may include a lower active region LAR and an upper active region UAR sequentially stacked on the substrate 100. One of the lower or upper active regions LAR and UAR may be a PMOSFET region. The other one of the lower or upper active regions LAR and UAR may be an NMOSFET region. The lower active region LAR may be disposed in the bottom tier of the FEOL layer, and the upper active region UAR may be disposed in the top tier of the FEOL layer. The NMOSFET and PMOSFET of the lower and upper active regions LAR and UAR may be vertically stacked to constitute a three-dimensional stacked transistor. For example, the lower active region LAR may be an NMOSFET region, and the upper active region UAR may be a PMOSFET region.

Each of the lower and upper active regions LAR and UAR may have a bar shape or a line shape extending in a second direction D2 intersecting the first direction D1, wherein the first and second directions D1 and D2 may be perpendicular to the third direction D3. Each of gate cutting patterns CTP, which will be described later, may be disposed between the single height cells SHC adjacent to each other in the first direction D1. Accordingly, the single height cells SHC may be spaced apart from each other in the first direction D1.

The lower active region LAR of each single height cell SHC may include lower channel patterns LCH and lower source/drain patterns LSD. Each of the lower channel patterns LCH may be disposed between a pair of lower source/drain patterns LSD. Each of the lower channel patterns LCH may connect a pair of lower source/drain patterns LSD to each other.

Each of the lower channel patterns LCH may include a first semiconductor pattern SP1 and a second semiconductor pattern SP2 that are stacked and spaced apart from each other. Each of the first and second semiconductor patterns SP1 and SP2 may include silicon (Si), germanium (Ge), or silicon germanium (SiGe). In detail, each of the first and second semiconductor patterns SP1 and SP2 may include crystalline silicon. Each of the first and second semiconductor patterns SP1 and SP2 may be a nanosheet. According to an embodiment, each of the lower channel patterns LCH may further include one or more semiconductor patterns that are stacked and spaced apart from the first semiconductor pattern SP1. The first semiconductor pattern SP1 may be the lowest semiconductor pattern among semiconductor patterns.

The lower source/drain patterns LSD may be disposed on the substrate 100. Each of the lower source/drain patterns LSD may be an epitaxial pattern formed through a selective epitaxial growth (SEG) process. For example, upper surfaces of the lower source/drain patterns LSD may be higher than an upper surface of the second semiconductor pattern SP2 of each of the lower channel patterns LCH.

The lower source/drain patterns LSD may be doped with impurities to have a first conductivity type. The first conductivity type may be N-type or P-type, and more specifically, the first conductivity type may be N-type. The lower source/drain patterns LSD may include silicon (Si) and/or silicon germanium (SiGe).

A first interlayer insulating layer 110 may be disposed on the lower source/drain patterns LSD. The first interlayer insulating layer 110 may cover the lower source/drain patterns LSD.

Lower active contacts LAC may be disposed below the lower source/drain patterns LSD, respectively. Each of the lower active contacts LAC may be electrically connected to the corresponding lower source/drain patterns LSD. The lower active contacts LAC may be buried in the substrate 100. The lower active contacts LAC may extend from the second surface 100b of the substrate 100 to the first surface 100t in the third direction D3. For example, the lower active contacts LAC may include at least one of copper (Cu), aluminum (Al), ruthenium (Ru), cobalt (Co), tungsten (W), or molybdenum (Mo).

An upper active region UAR may be disposed on the first interlayer insulating layer 110. The upper active region UAR may include upper channel patterns UCH and upper source/drain patterns USD. The upper channel patterns UCH may vertically overlap the lower channel patterns LCH. The upper source/drain patterns USD may vertically overlap the lower source/drain patterns LSD, respectively. Each of the upper channel patterns UCH may be disposed between a pair of upper source/drain patterns USD. Each of the upper channel patterns UCH may connect a pair of upper source/drain patterns USD to each other.

Each of the upper channel patterns UCH may include a third semiconductor pattern SP3 and a fourth semiconductor pattern SP4 that are stacked and spaced apart from each other. The third and fourth semiconductor patterns SP3 and SP4 of the upper channel patterns UCH may include substantially the same semiconductor material as the first and second semiconductor patterns SP1 and SP2 of the lower channel patterns LCH. Each of the third and fourth semiconductor patterns SP3 and SP4 may be a nanosheet. According to an embodiment, each of the upper channel patterns UCH may further include one or more semiconductor patterns stacked to be spaced apart from the third semiconductor pattern SP3.

Dummy channel patterns DSP may be disposed between the lower channel patterns LCH and upper channel patterns UCH that vertically overlap each other. A portion of the first interlayer insulating layer 110 may be disposed between the dummy channel patterns DSP. Accordingly, the dummy channel patterns DSP may be spaced apart from the lower and upper source/drain patterns LSD and USD. That is, the dummy channel patterns DSP may not be connected to any source/drain patterns and may be isolated from the source/drain patterns. For example, dummy channel patterns DSP may include semiconductor materials such as silicon (Si), germanium (Ge), or silicon germanium (SiGe), or silicon-based insulating materials such as silicon oxide or silicon nitride.

A seed layer SDL may be disposed between the dummy channel patterns DSP and the upper channel patterns UCH.

The upper source/drain patterns USD may be disposed on an upper surface of the first interlayer insulating layer 110. Each of the upper source/drain patterns USD may be an epitaxial pattern formed through a selective epitaxial growth (SEG) process. For example, upper surfaces of the upper source/drain patterns USD may be higher than an upper surface of the fourth semiconductor pattern SP4 of each of the upper channel patterns UCH.

The upper source/drain patterns USD may be doped with impurities to have a second conductivity type. The second conductivity type may be different from the first conductivity type of the lower source/drain patterns LSD. For example, the second conductivity type may be P-type. The upper source/drain patterns USD may include silicon germanium (SiGe) and/or silicon (Si).

A second interlayer insulating layer 120 may be disposed on the upper source/drain patterns USD. The second interlayer insulating layer 120 may cover the upper source/drain patterns USD. The second interlayer insulating layer 120 may have an upper surface substantially the same height as upper surfaces of the gate capping patterns GP, which will be described later.

A plurality of gate electrodes GE may be disposed on single height cells SHC. When viewed in a plan view, each of the gate electrodes GE may have a bar shape extending in the first direction D1. For example, gate electrodes GE may be disposed on the stacked lower and upper channel patterns LCH and UCH. The gate electrodes GE may vertically overlap the stacked lower and upper channel patterns LCH and UCH.

Each of the gate electrodes GE may be disposed on an upper surface, a lower surface, and both sidewalls of each of the first to fourth semiconductor patterns SP1 to SP4. A transistor according to some embodiments may include a three-dimensional field effect transistor (e.g., MBCFET or GAAFET) in which gate electrodes GE three-dimensionally surround a channel.

Each of the gate electrodes GE may include a lower gate electrode LGE disposed in the lower active region LAR and an upper gate electrode UGE disposed in the upper active region UAR. The lower gate electrode LGE and the upper gate electrode UGE may be distinguished based on the dummy channel patterns DSP. The lower gate electrode LGE and the upper gate electrode UGE may be connected to each other, but are not limited thereto.

The lower gate electrode LGE may include a first inner electrode POI between a first lower insulating pattern LIP1, which will be described later, and the first semiconductor pattern SP1, a second inner electrode PO2 between the first semiconductor pattern SP1 and the second semiconductor pattern SP2, and a third inner electrode PO3 between the second semiconductor pattern SP2 and the dummy channel patterns DSP.

The upper gate electrode UGE may include a fourth inner electrode PO4 between the dummy channel patterns DSP and the third semiconductor pattern SP3, a fifth inner electrode PO5 between the third semiconductor pattern SP3 and the fourth semiconductor pattern SP4, and an outer electrode PO6 on the fourth semiconductor pattern SP4.

A pair of gate spacers GS may be disposed on sidewalls of the gate electrodes GE, respectively. For example, a pair of gate spacers GS may be disposed on both sidewalls of the outer electrode PO6. The gate spacers GS may extend in the first direction D1 along the gate electrodes GE. Upper surfaces of the gate spacers GS may be higher than upper surfaces of the gate electrodes GE. The upper surfaces of the gate spacers GS may be coplanar with upper surfaces of gate capping patterns GP, which will be described later. For example, the gate spacers GS may include at least one of SiCN, SiCON, or SiN. Alternatively, the gate spacers GS may include a multi-layer formed of at least two of SiCN, SiCON, and SiN.

Gate capping patterns GP may be disposed on each of the gate electrodes GE. Each of the gate capping patterns GP may extend in the first direction D1 along the gate electrodes GE. For example, the gate capping patterns GP may include at least one of SiON, SiCN, SiCON, or SiN.

A gate insulating layer GI may be disposed between the gate electrodes GE and the first to fourth semiconductor patterns SP1, SP2, SP3, and SP4. For example, the gate insulating layer GI may include a silicon oxide layer, a silicon oxynitride layer, and/or a high-k dielectric layer. Alternatively, the gate insulating layer GI may include a silicon oxide layer directly covering surfaces of the first to fourth semiconductor patterns SP1, SP2, SP3, and SP4, and a high-k dielectric layer on the silicon oxide layer. That is, the gate insulating layer GI may include a multi-layer of a silicon oxide layer and a high-k dielectric layer.

The high-k dielectric layer of the gate insulating layer GI may include a high-k dielectric constant material that has a higher dielectric constant than the silicon oxide layer. For example, the high dielectric constant materials may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium. oxide, lithium oxide, aluminum oxide, lead scandium tantalum oxide, or lead zinc niobate.

According to an embodiment, the lower gate electrode LGE may further include a first work function metal pattern on the first and second semiconductor patterns SP1 and SP2. The upper gate electrode UGE may further include a second work function metal pattern on the third and fourth semiconductor patterns SP3 and SP4. Each of the first and second work function metal patterns may include a metal including at least one of titanium (Ti), tantalum (Ta), aluminum (Al), tungsten (W), and molybdenum (Mo) or nitrogen (N). The first and second work function metal patterns may have different work functions. Additionally, the gate electrodes GE may further include a low-resistance metal (e.g., at least one of tungsten (W), ruthenium (Ru), aluminum (Al), titanium (Ti), or tantalum (Ta)) on the first and second work function metal patterns. In this case, the outer electrode PO6 may include a low-resistance metal as well as the second work function metal pattern.

A third interlayer insulating layer 130 may be disposed on the gate capping patterns GP. An upper surface of the third interlayer insulating layer 130 may be coplanar with upper surfaces of upper active contacts UAC, which will be described later.

A gate contact GC may penetrate the third interlayer insulating layer 130 and the gate capping patterns GP. The gate contact GC may be electrically connected to the upper gate electrode UGE. For example, the upper active contacts UAC and the gate contact GC may include a metal including at least one of copper (Cu), aluminum (Al), ruthenium (Ru), cobalt (Co), tungsten (W), or molybdenum (Mo).

Gate cutting patterns CTP may intersect the gate electrodes GE extending in the first direction D1. For example, the gate cutting patterns CTP may extend in the second direction D2. Each of the gate cutting patterns CTP may extend in the second direction D2 and may be configured to separate the gate electrodes GE extending in the first direction D1. The gate cutting patterns CTP may penetrate the gate electrodes GE in the third direction D3. For example, upper surfaces CTPt of the gate cutting patterns CTP may be coplanar with upper surfaces of the gate capping patterns GP on the gate electrodes GE. Lower surfaces CTPb of the gate cutting patterns CTP may be coplanar with the second surface 100b of the substrate 100 below the gate electrodes GE. That is, the upper surfaces CTPt of the gate cutting patterns CTP may be higher than upper surfaces GEt of the gate electrodes GE. The lower surfaces CTPb of the gate cutting patterns CTP may be lower than lower surfaces GEb of the gate electrodes GE.

A vertical length of each of the gate cutting patterns CTP may be greater than a vertical length of each of the gate electrodes GE. The gate electrodes GE may be separated in the first direction D1 by the gate cutting patterns CTP. When viewed in a plan view, each of the gate cutting patterns CTP may have a bar shape or a line shape extending in the second direction D2. The gate cutting patterns CTP may be spaced apart from each other in the first direction D1.

Each of the gate cutting patterns CTP may have an upper width TW in the first direction D1 at the upper surface CTPt thereof. Each of the gate cutting patterns CTP may have a lower width BW in the first direction D1 at the lower surface CTPb thereof. The upper width TW and the lower width BW may be different each other. For example, the upper width TW may be smaller than the lower width BW, but is not limited thereto. According to an embodiment, the upper width TW and the lower width BW may be substantially the same.

Each of the gate cutting patterns CTP may include a buried insulating layer FIL and a liner layer DMP. The buried insulating layer FIL and the liner layer DMP may be in contact with each other. The liner layer DMP may be disposed on a sidewall of the buried insulating layer FIL and may surround the sidewall of the buried insulating layer FIL. For example, the liner layer DMP may be disposed on opposing sidewalls of the buried insulating layer FIL spaced apart in the first direction D1. The buried insulating layer FIL and the liner layer DMP may include at least one of SiO, SiON, SiCN, SiCON, or SiN. Alternatively, the liner layer DMP may be an insulating layer composed of one layer or multiple layers. According to an embodiment, the buried insulating layer FIL and the liner layer DMP may include different insulating materials. In this case, the buried insulating layer FIL and the liner layer DMP may have an etch selectivity to each other.

Additionally, the buried insulating layer FIL of each of the gate cutting patterns CTP may include a first portion Pl and a second portion P2. The first portion P1 may be disposed on the second portion P2. For example, the first portion P1 may correspond to an upper portion of each of the gate cutting patterns CTP, and the second portion P2 may correspond to a lower portion of each of the gate cutting patterns CTP. The first portion P1 may be adjacent to the upper active region UAR, and the second portion P2 may be adjacent to the lower active region LAR. Additionally, the first portion P1 and the second portion P2 may be in contact with each other. According to an embodiment, the first portion P1 and the second portion P2 may include the same insulating material. In this case, an interface formed by the first portion P1 and the second portion P2 being in contact with each other may be invisible.

A fourth interlayer insulating layer 140 may be disposed on the third interlayer insulating layer 130. A first metal layer M1 may be disposed in the fourth interlayer insulating layer 140. The first metal layer M1 may include upper interconnections UMI. The first metal layer M1 may further include upper vias UVI. The upper vias UVI may electrically connect the upper interconnections UMI and the upper active contacts UAC or the gate contact GC. Each of the upper interconnections UMI and upper vias UVI may include a metal including at least one of copper (Cu), aluminum (Al), ruthenium (Ru), cobalt (Co), tungsten (W), or molybdenum (Mo).

According to an embodiment, a plurality of metal layers (e.g., M2, M3, M4, etc.) may be disposed on the first metal layer M1. In this case, the first metal layer M1 and a plurality of metal layers on the first metal layer M1 may form a back end of line (BEOL) layer of a three-dimensional semiconductor device. For example, a plurality of metal layers on the first metal layer M1 may include routing wirings for connecting adjacent logic cells to each other.

A first lower interlayer insulating layer 200 may be disposed on the second surface 100b of the substrate 100. A second lower interlayer insulating layer 210 may be disposed below the first lower interlayer insulating layer 200. A backside metal layer BSM may be disposed in the second lower interlayer insulating layer 210. The backside metal layer BSM may include lower interconnections LMI. The backside metal layer BSM may further include lower vias LVI. The lower vias LVI may electrically connect the lower active contacts LAC and the lower interconnections LMI. Each of the lower interconnections LMI and the lower vias LVI may include a metal including at least one of copper (Cu), aluminum (Al), ruthenium (Ru), cobalt (Co), tungsten (W), or molybdenum (Mo).

According to an embodiment, a plurality of lower metal layers may be disposed below the backside metal layer BSM. For example, the plurality of lower metal layers may include a power transmission network layer. The power transmission network layer may include a wiring network for applying source voltage and/or drain voltage to the backside metal layer BSM. In this case, one of the source voltage or the drain voltage may be applied to the lower source/drain patterns LSD through the lower interconnections LMI, the lower vias LVI, and the lower active contacts LAC. The other of the source voltage or the drain voltage may be applied from the backside metal layer BSM to the first metal layer M1 through a power tap cell. The voltage applied to the first metal layer M1 through the power tap cell may be applied to the upper contacts UAC through the upper interconnections UMI, the upper vias UVI, and the upper active contacts UAC.

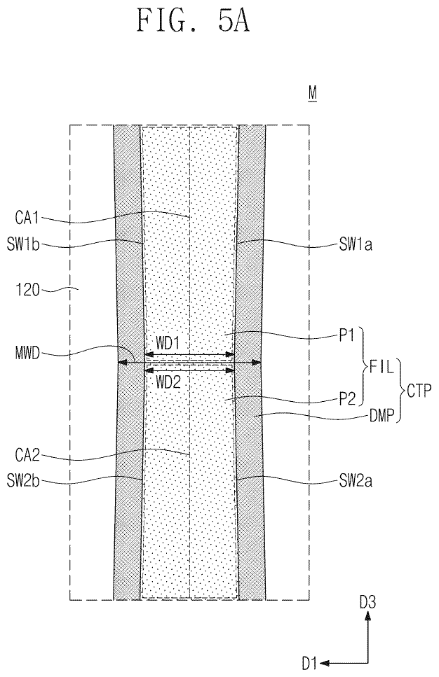

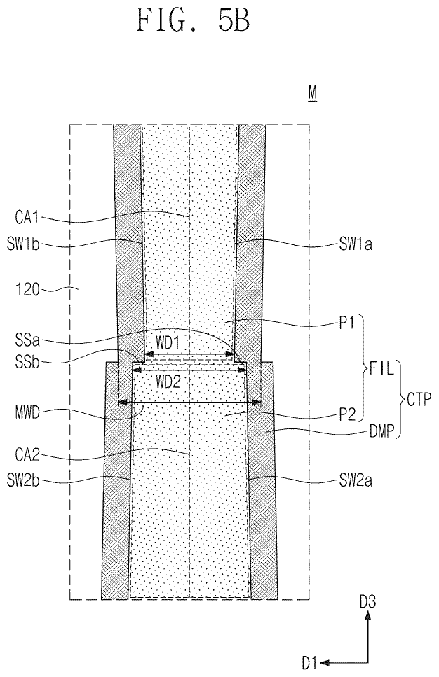

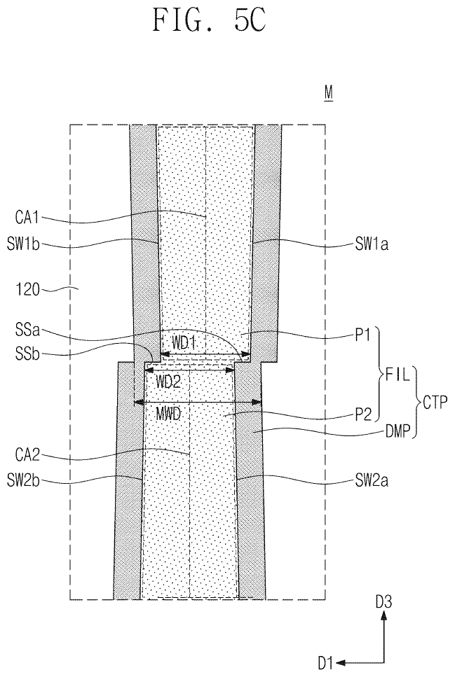

FIGS. 5A to 5C are diagrams for explaining a gate cutting pattern of a three-dimensional semiconductor device according to embodiments of the inventive concept, and are enlarged views of region ‘M’ of FIG. 4C.

Referring to FIG. 5A, the buried insulating layer FIL of the gate cutting pattern CTP may include a first portion P1 and a second portion P2 below the first portion P1. Each of the first portion P1 and the second portion P2 may have a shape extending in the third direction D3. For example, the first portion P1 and the second portion P2 may be in contact with each other to form the buried insulating layer FIL extending in the third direction D3.

Each of the first portion P1 and the second portion P2 may have a width in the first direction D1. The width of each of the first portion P1 and the second portion P2 may be variously changed depending on a height (or a level). For example, the first portion P1 may have a width that decreases as the first portion P1 approaches the second portion P2. The second portion P2 may have a width that decreases as the second portion P2 approaches the first portion P1.

The first portion P1 may have a first width WD1 at an interface where the first portion P1 is in contact with the second portion P2. The second portion P2 may have a second width WD2 at the interface where the second portion P2 is in contact with the first portion P1. The first width WD1 and the second width WD2 may be substantially the same each other. The first width WD1 and the second width WD2 may be less than the upper width TW of an upper portion of the gate cutting pattern CTP. The first width WD1 and the second width WD2 may be less than the lower width BW of a lower portion of the gate cutting pattern CTP. For example, the first portion P1 may have a first width WD1 that may be a minimum width at an interface where the first portion P1 is in contact with the second portion P2. The second portion P2 may have a second width WD2 that may be a minimum width at the interface where the second portion P2 is in contact with the first portion P1. The first width WD1 and the second width WD2 may be substantially the same each other. Accordingly, the gate cutting pattern CTP may have a middle width MWD at the interface where the first portion P1 and the second portion P2 are in contact with each other. The middle width MWD may be a minimum width of the buried insulating layer FIL, but embodiments are not limited thereto.

The first portion P1 and the second portion P2 of the buried insulating layer FIL may each be tapered to a portion where the first portion P1 and the second portion P2 meet. For example, in the third direction, the buried insulating layer FIL may have a converging shape at a portion corresponding to the second portion P2 and may have a diverging shape at a portion corresponding to the first portion P1.

The first portion P1 may have a first upper sidewall SW1a and a second upper sidewall SW1b facing each other in the first direction D1. The second portion P2 may have a first lower sidewall SW2a and a second lower sidewall SW2b facing each other in the first direction D1. The first upper sidewall SW1a and the first lower sidewall SW2a may be connected to each other. The second upper sidewall SW1b and the second lower sidewall SW2b may be connected to each other. The first upper sidewall SW la may extend from the first lower sidewall SW2a, and the first upper sidewall SW1a, and the first lower sidewall SW2a may extend substantially in the third direction D3 with respective tapers. The second upper sidewall SW1b may extend from the second lower sidewall SW2b, and the second upper sidewall SW1b and the second lower sidewall SW2b may extend substantially in the third direction D3 with respective tapers. For example, the sidewalls of the buried insulating layer FIL may not have a step.

The first portion P1 may have a first central axis CA1 passing through a center of the first portion P1 along the first direction D1. The second portion P2 may have a second central axis CA2 passing through a center of the second portion P2 along the first direction D1. Each of the first central axis CA1 and the second central axis CA2 may extend in the third direction D3. The first central axis CA1 and the second central axis CA2 may not be spaced apart from each other in the first direction D1 and may be aligned with each other.

A liner layer DMP may be disposed between the first and second portions P1 and P2 and the second interlayer insulating layer 120. The liner layer DMP may have a uniform thickness and may cover the first and second upper sidewalls SW1a and SW1b of the first portion P1 and the first and second lower sidewalls SW2a and SW2b of the second portion P2.

Referring to FIG. 5B, the buried insulating layer FIL of the gate cutting pattern CTP may include a first portion P1 and a second portion P2, and each of the first portion P1 and the second portion P2 may have different widths in the first direction D1. Additionally, the first portion P1 and the second portion P2 may have a width that decreases as the first and second portions P1 and P2 are adjacent to each other.

The first portion P1 may have a first width WD1 at an interface where the first portion P1 is in contact with the second portion P2. The second portion P2 may have a second width WD2 at the interface where the second portion P2 is in contact with the first portion P1. The first width WD1 and the second width WD2 may be different widths. The first width WD1 and the second width WD2 may be less than the upper width TW of the gate cutting pattern CTP. The first width WD1 and the second width WD2 may be less than the lower width BW of the gate cutting pattern CTP. For example, the first portion P1 may have a first width WD1 that may be a minimum width at an interface where the first portion P1 is in contact with the second portion P2. The second portion P2 may have a second width WD2 that may be a minimum width at the interface where the second portion P2 is in contact with the first portion P1. The first width WD1 and the second width WD2 may be different from each other. For example, the first width WD1 may be smaller than the second width WD2. Similar to FIG. 5A, the gate cutting pattern CTP may have a middle width MWD at the interface where the first portion P1 and the second portion P2 are in contact with each other. The middle width MWD may be a minimum width of the buried insulating layer FIL, but embodiments are not limited thereto. One of the first width WD1 or the second width WD2 may be associated with the middle width MWD at the interface where the first portion P1 and the second portion P2 are in contact with each other. For example, FIG. 5B illustrates a case where the first width WD1 is associated with the middle width MWD, however embodiments are not limited thereto. For example, the second width WD2 may be associated with the middle width MWD.

The gate cutting pattern CTP may have a first step surface SSa between the first upper sidewall SW1a and the first lower sidewall SW2a and a second step surface SSb between the second upper sidewall SW1b and the second lower sidewall SW2b. For example, either the first step surface SSa or the second step surface SSb may be omitted. That is, the gate cutting pattern CTP may have at least one step surface between the sidewall of the first portion P1 and the sidewall of the second portion P2.

The first central axis CA1 of the first portion P1 along the first direction D1 and the second central axis CA2 of the second portion P2 along the first direction D1 may be aligned with each other. However, the inventive concept is not limited thereto. For example, the first central axis CA1 and the second central axis CA2 may be spaced apart from each other in the first direction D1.

The liner layer DMP may be disposed between the first and second portions P1 and P2 and the second interlayer insulating layer 120. The liner layer DMP may cover the buried insulating layer FIL with a uniform thickness. For example, the liner layer DMP may cover the first and second upper sidewalls SW1a and SW1b, the first and second lower sidewalls SW2a and SW2b, and the first and second step surfaces SSa and SSb. Accordingly, the liner layer DMP may also have step surfaces adjacent to the interface where the first portion P1 and the second portion P2 are in contact with each other.

Referring to FIG. 5C, the buried insulating layer FIL of the gate cutting pattern CTP may include a first portion P1 and a second portion P2. The first portion P1 may have a first central axis CA1 passing through a center of the first portion P1 along the first direction D1, and the second portion P2 may have a second central axis CA2 passing through a center of the second portion P2 along the first direction D1. The first central axis CA1 and the second central axis CA2 may be spaced apart from each other in the first direction D1. That is, the first central axis CA1 and the second central axis CA2 may be offset in the first direction D1. Accordingly, the first portion P1 may vertically overlap a portion of the second portion P2.

Each of the first portion P1 and the second portion P2 may have a first width WD1 and a second width WD2 at the interface where the first portion P1 and the second portion P2 are in contact with each other, similar to FIG. 5A. Additionally, the first width WD1 and the second width WD2 may be substantially the same. For example, the first portion P1 may have a first width WD1 at an interface where the first portion P1 is in contact with the second portion P2. The second portion P2 may have a second width WD2 at the interface where the second portion P2 is in contact with the first portion P1. The first width WD1 and the second width WD2 may be substantially the same each other. The first width WD1 and the second width WD2 may be less than the upper width TW of the gate cutting pattern CTP. The first width WD1 and the second width WD2 may be less than the lower width BW of the gate cutting pattern CTP. Accordingly, the buried insulating layer FIL may have a middle width MWD at the interface where the first portion P1 and the second portion P2 are in contact with each other. The middle width MWD may be a minimum width of the buried insulating layer FIL, but embodiments are not limited thereto.

As the first central axis CA1 of the first portion P1 and the second central axis CA2 of the second portion P2 are spaced apart from each other in the buried insulating layer FIL, the first portion P1 and the second portion P2 may have step surfaces therebetween. For example, the first step surface SSa may be disposed between the first upper sidewall SW1a and the first lower sidewall SW2a, and the second step surface SSb may be disposed between the second upper sidewall SW1b and the second lower sidewall SW2b. The first step surface SSa and the second step surface SSb may be coplanar, but are not limited thereto. According to an embodiment, the first step surface SSa and the second step surface SSb may be disposed at different levels.

The liner layer DMP between the buried insulating layer FIL and the second interlayer insulating layer 120 may cover the buried insulating layer FIL with a uniform thickness. Accordingly, the liner layer DMP may also have step surfaces adjacent to the interface where the first portion P1 and the second portion P2 are in contact with each other.

Referring again to FIGS. 4A to 4D and FIGS. 5A to 5C, according to embodiments of the inventive concept, the first portion P1 of the gate cutting pattern CTP may be formed on the first surface 100t of the substrate 100, and the second portion P2 may be formed on the second surface 100b of the substrate 100. The first portion P1 and the second portion P2 may be formed separately to form the buried insulating layer FIL. Accordingly, the width of the gate cutting pattern CTP may be relatively small at the interface where the first portion P1 and the second portion P2 are in contact with each other. That is, the gate cutting pattern CTP may have a minimum width at the middle width MWD between the upper surface CTPt and the lower surface CTPb of the gate cutting pattern CTP. Additionally, as the first portion P1 and the second portion P2 may be formed through different processes, the gate cutting pattern CTP with a high aspect ratio may be filled with an insulating material while inhibiting or preventing voids. Accordingly, electrical characteristics and reliability of a three-dimensional semiconductor device may be improved.

In other words, as the gate cutting pattern CTP for separating the gate electrodes GE may be formed through multiple processes, a size of a recess for forming the gate cutting pattern CTP may be smaller. Additionally, a recess for forming the first portion P1 may be smaller than a recess for forming the second portion P2. The upper width TW of the gate cutting pattern CTP may be smaller than the lower width BW thereof, and a distance between semiconductor circuit patterns integrated on the first surface 100t of the substrate 100 may be narrowed. Therefore, integration of three-dimensional semiconductor devices may be improved.

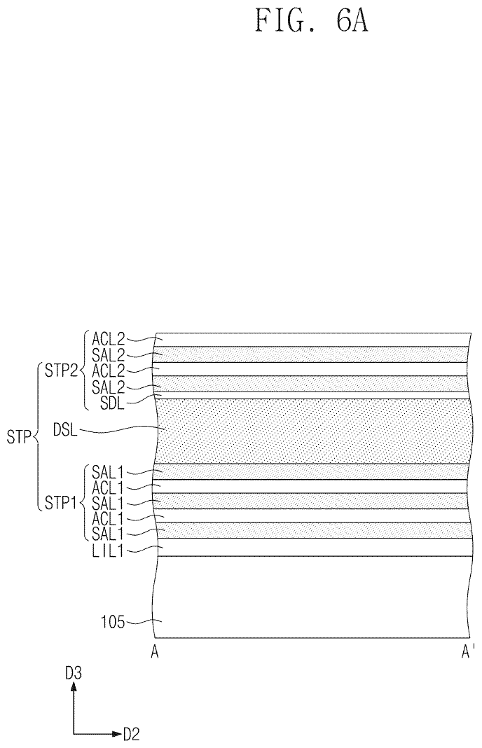

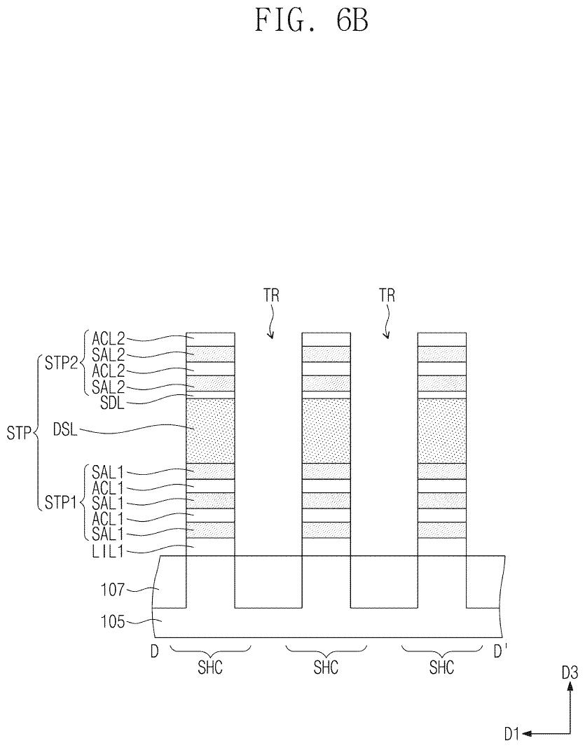

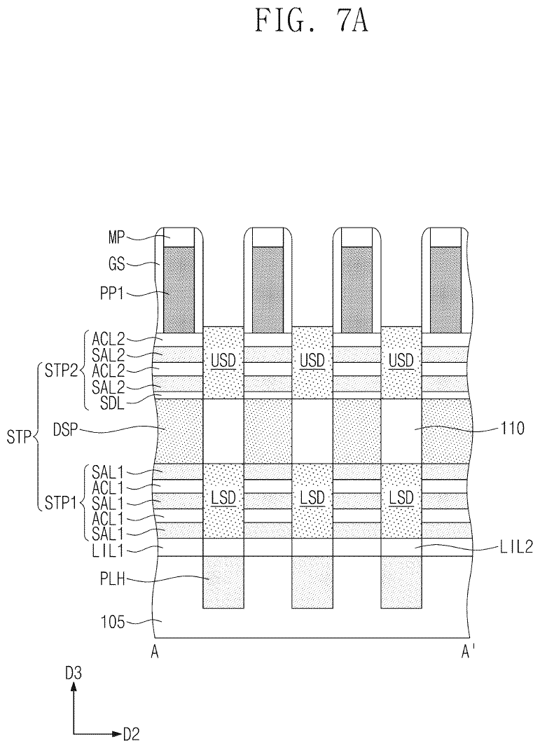

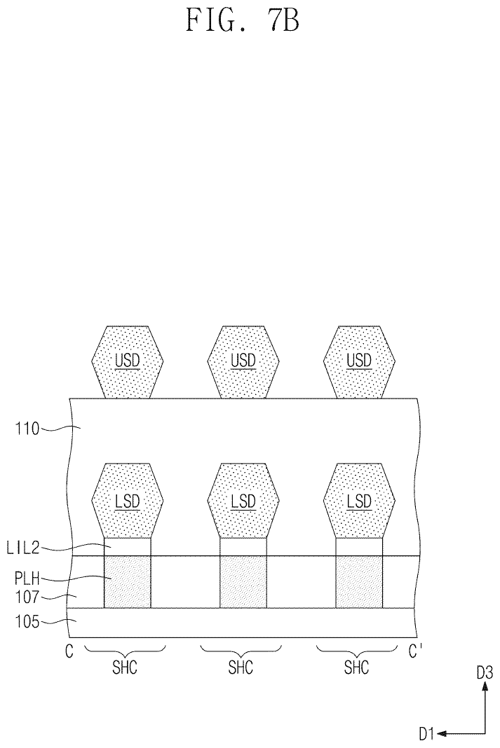

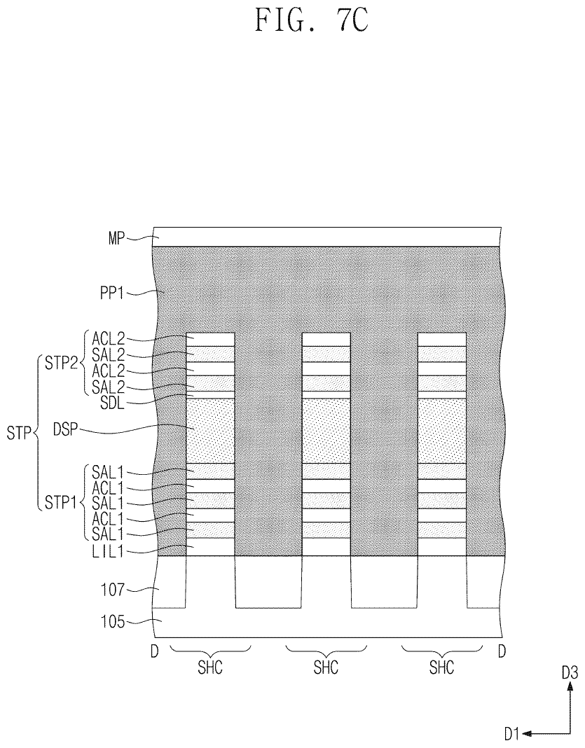

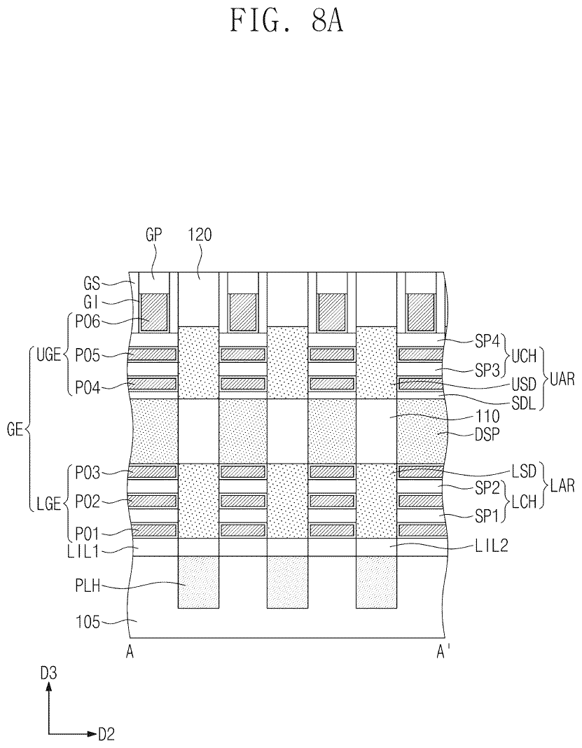

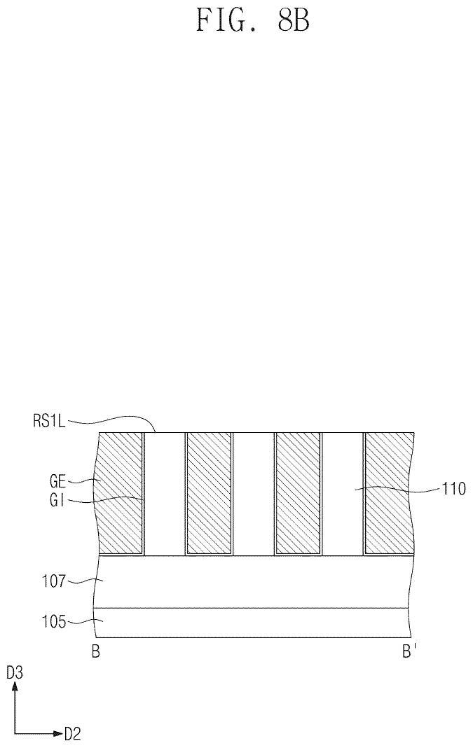

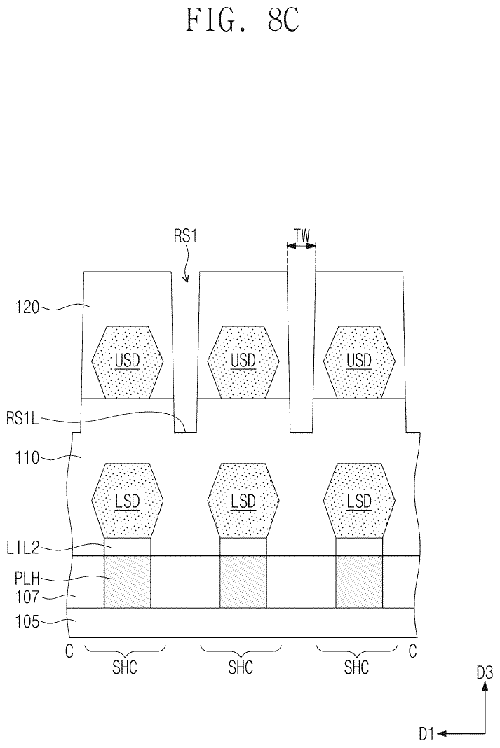

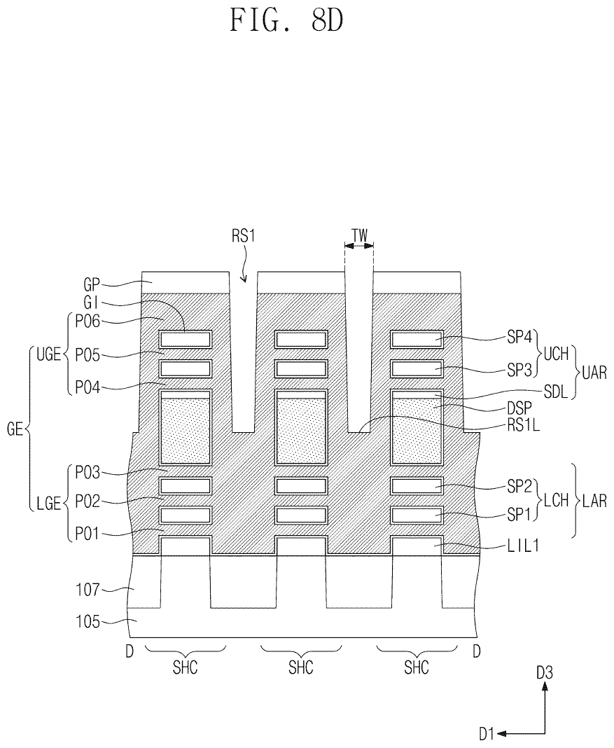

FIGS. 6A and 6B, FIGS. 7A to 7C, FIGS. 8A to 8D, FIGS. 9A to 9D, FIGS. 10A to 10D, and FIGS. 11A to 11D are diagrams for explaining a method of manufacturing a three-dimensional semiconductor device according to embodiments of the inventive concept, FIGS. 6A, 7A, 8A, 9A, 10A, and 11A are cross-sectional views taken along line A-A′ of FIG. 3, FIGS. 8B, 9B, 10B, and 11B are cross-sectional views taken along line B-B′ of FIG. 3, FIGS. 7B, 8C, 9C, and 10C, and FIG. 11C are cross-sectional views taken along line C-C′ of FIG. 3, and FIGS. 6B, 7C, 8D, 9D, 10D, and FIG. 11D are cross-sectional views taken along line D-D′ of FIG. 3.

Referring to FIGS. 6A and 6B, a semiconductor substrate 105 may be provided. The semiconductor substrate 105 may include at least one of silicon (Si), germanium (Ge), or silicon-germanium (SiGe). For example, the semiconductor substrate 105 may be a single crystal silicon wafer.

A first lower insulating layer LIL1 may be formed on the semiconductor substrate 105. The first lower insulating layer LIL1 may include a silicon-based insulating material (e.g., silicon oxide) and/or a semiconductor material (e.g., Si or SiGe).

First sacrificial layers SAL1 and first active layers ACL1 may be alternately formed on the first lower insulating layer LIL1. The first sacrificial layers SAL1 may include at least one of silicon (Si), germanium (Ge), or silicon germanium (SiGe), and the first active layers ACL1 may include at least one of silicon (Si), germanium (Ge) or silicon germanium (SiGe). For example, the first sacrificial layers SAL1 may include silicon germanium (SiGe), and the first active layers ACL1 may include silicon (Si). A concentration of germanium (Ge) in each of the first sacrificial layers SAL1 may be about 10 at % to about 30 at %.

A separation layer DSL may be formed on the uppermost one of the first sacrificial layers SAL1. For example, a thickness of the separation layer DSL may be greater than a thickness of each of the first sacrificial layers SAL1. The separation layer DSL may include silicon (Si) or silicon germanium (SiGe). When the separation layer DSL includes silicon germanium (SiGe), a concentration of germanium (Ge) in the separation layer DSL may be greater than a concentration of germanium (Ge) in the first sacrificial layers SAL1. For example, the concentration of germanium (Ge) in the separation layer DSL may be about 40 at % to about 90 at %.

A seed layer SDL may be formed on the separation layer DSL. The seed layer SDL may include the same material as the first active layers ACL1. Second sacrificial layers SAL2 and second active layers ACL2 may be alternately formed on the seed layer SDL. The second sacrificial layers SAL2 may include the same material as the first sacrificial layers SAL1, and the second active layers ACL2 may include the same material as the first active layers ACL1.

A stacked pattern STP may be formed by patterning the first and second sacrificial layers SAL1 and SAL2, the first and second active layers ACL1 and ACL2, and the separation layer DSL. Forming the stacked pattern STP may include forming a hard mask pattern on the uppermost layer among the second active layers ACL2, and etching the first and second sacrificial layers SAL1 and SAL2, the active layers ACL1 and ACL2, and the separation layer DSL using the hard mask pattern as an etch mask to partially remove the first and second sacrificial layers SAL1 and SAL2, the active layers ACL1 and ACL2, and the separation layer DSL. While the stacked pattern STP is formed, an upper portion of the semiconductor substrate 105 may be patterned to form a trench TR defining a single height cell SHC. The stacked pattern STP may have a bar shape or a line shape extending in a second direction D2.

The stacked pattern STP may include a lower stacked pattern STP1 on the first lower insulating layer LIL1, an upper stacked pattern STP2 on the lower stacked pattern STP1, and a separation layer DSL between the lower and upper stacked patterns STP1 and STP2. The lower stacked pattern STP1 may include first sacrificial layers SAL1 and first active layers ACL1 that are alternately stacked. The upper stacked pattern STP2 may include a seed layer SDL, second sacrificial layers SAL2 and second active layers ACL2 alternately stacked on the seed layer SDL.

While the stacked pattern STP is illustrated in FIG. 7C as including the lower stacked pattern STP1 with two active layers ACL1 and three first sacrificial layers SAL1, and the upper stacked pattern STP2 with two active layers ACL2 and three second sacrificial layers SAL2, the number of layers may be varied. For example, the number of active layers and/or the number of sacrificial layers may be varied to control a number of layers in a channel pattern and/or a gate electrode formed later.

A device isolation layer 107 may be formed on an exposed portion of the semiconductor substrate 105 in the trench TR. For example, the device isolation layer 107 may be formed on the semiconductor substrate 105 to fill a lower portion of the trench TR. Forming the device isolation layer 107 may include forming an insulating layer covering the stacked patterns STP on the surface of the semiconductor substrate 105, and recessing the insulating layer at least until the stacked patterns STP are exposed. For example, an upper surface of the device isolation layer 107 may be coplanar with an upper surface of the semiconductor substrate 105. Further, the insulating layer may cover the stacked patterns STP on the surface of the semiconductor substrate 105.

Referring to FIGS. 7A, 7B, and 7C, a plurality of first sacrificial patterns PP1 may be formed on the stacked pattern STP, crossing the stacked pattern STP. Each of the first sacrificial patterns PP1 may be formed in a line shape extending in a first direction D1. Forming the first sacrificial patterns PP1 may include forming a sacrificial layer on the surface of the semiconductor substrate 105, forming a hard mask pattern MP on the sacrificial layer, and patterning the sacrificial layer using the hard mask pattern MP as an etch mask. For example, the sacrificial layer may include amorphous silicon and/or polysilicon formed on the entire surface of the semiconductor substrate 105.

A pair of gate spacers GS may be formed on both sidewalls of the first sacrificial patterns PP1, respectively. In detail, a spacer layer may be formed on the surface of the semiconductor substrate 105. The spacer layer may be formed on the entire surface of the semiconductor substrate 105 to have a uniform thickness. The spacer layer may cover the first sacrificial patterns PP1 and the hard mask pattern MP. The gate spacers GS may be formed by anisotropically etching the spacer layer. For example, the spacer layer may include at least one of SiCN, SiCON, or SiN.

Afterwards, an etching process using the gate spacers GS and the hard mask pattern MP may be performed on the stacked pattern STP. Due to the etching process, a recess may be formed between the first sacrificial patterns PP1 adjacent to each other in the second direction D2. The stacked pattern STP may have a shape extending in a third direction D3 due to the recess.

Sacrificial contact patterns PLH may be formed in the semiconductor substrate 105 exposed by the recess. The sacrificial contact patterns PLH may be formed in a contact shape. The sacrificial contact patterns PLH may be arranged in the second direction D2. The sacrificial contact patterns PLH may include a material that has etch selectivity with the semiconductor substrate 105, for example, silicon-germanium (SiGe). The sacrificial contact patterns PLH may be formed using an epitaxial growth process.

The separation layer DSL may be replaced with a silicon-based insulating material to form dummy channel patterns DSP. For example, the separation layer DSL exposed by the recess may be selectively removed. A silicon-based insulating material (e.g., silicon nitride) may be formed in a region from which the separation layer DSL has been removed. For example, the region from which the separation layer DSL has been removed may be filled with the silicon-based insulating material.

A second lower insulating layer LIL2 may be formed on the sacrificial contact patterns PLH. An upper surface of the second lower insulating layer LIL2 may be coplanar with an upper surface of the first lower insulating layer LIL1. The second lower insulating layer LIL2 may be formed of a silicon-based insulating material (e.g., silicon oxide, silicon oxynitride, or silicon nitride).

Lower source/drain patterns LSD may be formed on the second lower insulating layer LIL2. The lower source/drain patterns LSD may be formed through a selective epitaxial growth process using sidewalls of the lower stacked pattern STP1 as a seed layer exposed by the recess. For example, the lower source/drain patterns LSD may be grown using the first active layers ACL1 as a seed.

While the lower source/drain patterns LSD are being formed, impurities may be injected in-situ into the lower source/drain patterns LSD. Alternatively, impurities may be injected into the lower source/drain patterns LSD after the lower source/drain patterns LSD are formed. For example, the lower source/drain patterns LSD may be doped to have a first conductivity type (e.g., N-type).

A first interlayer insulating layer 110 may be formed to cover the lower source/drain patterns LSD. According to an embodiment, the first interlayer insulating layer 110 may be formed, after an insulating layer covering the lower source/drain patterns LSD is formed. For example, the first interlayer insulating layer 110 may be formed with a uniform thickness on the insulating layer covering the lower source/drain patterns LSD.

The first interlayer insulating layer 110 may expose sidewall of the upper stacked pattern STP2. Upper source/drain patterns USD may be formed on the first interlayer insulating layer 110. The upper source/drain patterns USD may be formed through a selective epitaxial growth process using the exposed sidewalls of the upper stacked pattern STP2 as a seed layer. For example, the upper source/drain patterns USD may be grown using the second active layers ACL2 as a seed. The upper source/drain patterns USD may be doped to have a second conductivity type (e.g., P type) different from the first conductivity type.

Referring to FIGS. 8A, 8B, 8C, and 8D, a second interlayer insulating layer 120 may be formed on the upper source/drain patterns USD. The second interlayer insulating layer 120 may cover the upper source/drain patterns USD. For example, the second interlayer insulating layer 120 may include a silicon oxide layer.

A planarization process may be performed on the second interlayer insulating layer 120 at least until upper surfaces of the first sacrificial patterns PP1 are exposed. For example, the planarization process may include an etch back or chemical mechanical polishing (CMP) process. The hard mask pattern MP on the first sacrificial patterns PP1 may be removed through a planarization process. Accordingly, an upper surface of the second interlayer insulating layer 120 may be coplanar with upper surfaces of the first sacrificial patterns PP1 and upper surfaces of the gate spacers GS.

The exposed first sacrificial patterns PP1 may be selectively removed. Removing the first sacrificial patterns PP1 may include a wet etching process using an etchant that selectively removes polysilicon. The first sacrificial patterns PP1 may be removed, and the first and second sacrificial layers SAL1 and SAL2 may be exposed to the outside.

After the first sacrificial patterns PP1 are removed, an etching process may be performed to selectively remove the exposed first and second sacrificial layers SAL1 and SAL2. Specifically, only the first and second sacrificial layers SAL1 and SAL2 may be removed while leaving the first to fourth semiconductor patterns SP1, SP2, SP3, and SP4 and dummy channel patterns DSP intact. The etching process for removing the first and second sacrificial layers SAL1 and SAL2 may have a high etch rate for silicon germanium. For example, the etching process may have a high etch rate for silicon germanium where the germanium concentration may be greater than about 10 at %.

A gate insulating layer GI may be in the space where the first sacrificial patterns PP1 and the first and second sacrificial layers SAL1 and SAL2 have been removed. The gate insulating layer GI may be formed to a uniform thickness. Gate electrodes GE may be formed on the gate insulating layer G1. Forming the gate electrodes GE may include forming first to fifth inner electrodes PO1, PO2, PO3, PO4, and PO5 between the first to fourth semiconductor patterns SP1, SP2, SP3, and SP4 and forming an outer electrode PO6 in a region where the first sacrificial patterns PP1 are removed.

Gate capping patterns GP may be formed on the gate electrodes GE. A planarization process may be performed on the gate capping patterns GP. The planarization process may be performed so that upper surfaces of the gate capping patterns GP are coplanar with an upper surface of the second interlayer insulating layer 120.

A lower active region LAR including a lower channel patterns LCH and the lower gate electrode LGE, and an upper active region UAR including an upper channel patterns UCH and an upper gate electrode UGE may be formed. Each of the lower channel patterns LCH may include first and second semiconductor patterns SP1 and SP2, and the first and second semiconductor patterns SP1 and SP2 may be formed from the first active layers ACL1. Each of the upper channel patterns UCH may include third and fourth semiconductor patterns SP3 and SP4, and the third and fourth semiconductor patterns SP3 and SP4 may be formed from the second active layers ACL2. First recesses RSI may be formed between the single height cells SHC. The first recesses RS1 may be formed through an etching process using a mask pattern on the second interlayer insulating layer 120 and the gate capping patterns GP. When viewed in a plan view, the first recesses RS1 may be spaced apart from each other in a first direction D1, and each of the first recesses RS1 may extend in the second direction D2. Each of the first recesses RS1 may have an upper width TW at an upper end thereof in the first direction D1.

The first recesses RS1 may penetrate the second interlayer insulating layer 120 and the gate capping patterns GP. For example, the first recesses RS1 may extend through the second interlayer insulating layer 120 and into the first interlayer insulating layer 110. Additionally, the first recesses RS1 may extend into the gate electrodes GE through the gate capping patterns GP. That is, the first recesses RS1 may penetrate a portion of the first interlayer insulating layer 110 and a portion of the gate electrodes GE. Accordingly, bottom surfaces RS1L of the first recesses RSI may be disposed in the first interlayer insulating layer 110 and the gate electrodes GE.

However, the inventive concept is not limited thereto. For example, the bottom surfaces RS1L of the first recesses RS1 may be coplanar with the upper surface of the first interlayer insulating layer 110 or a lower surface of the second interlayer insulating layer 120. Alternatively, the bottom surfaces RS1L of the first recesses RS1 may be disposed in the second interlayer insulating layer 120.

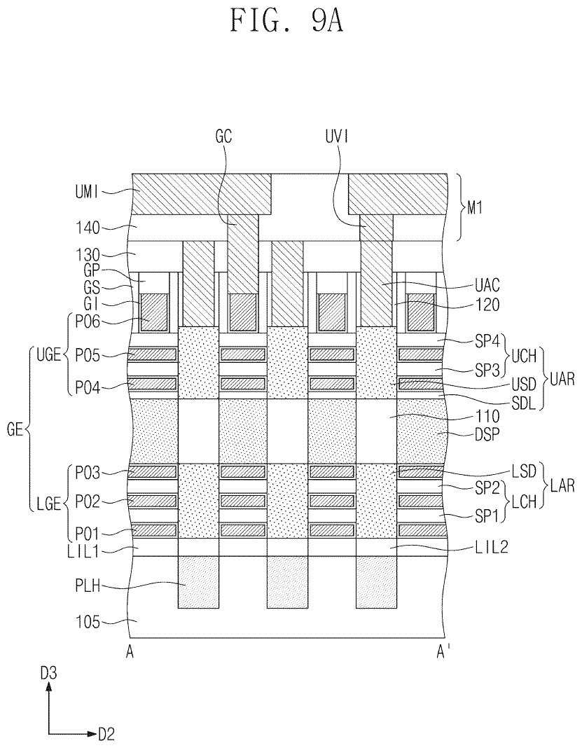

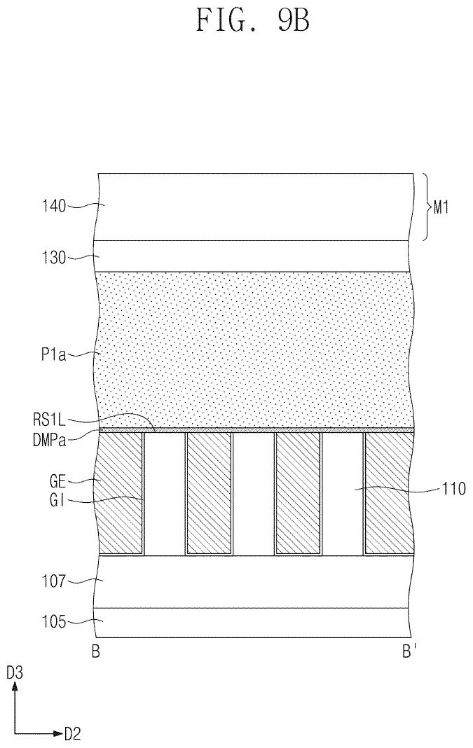

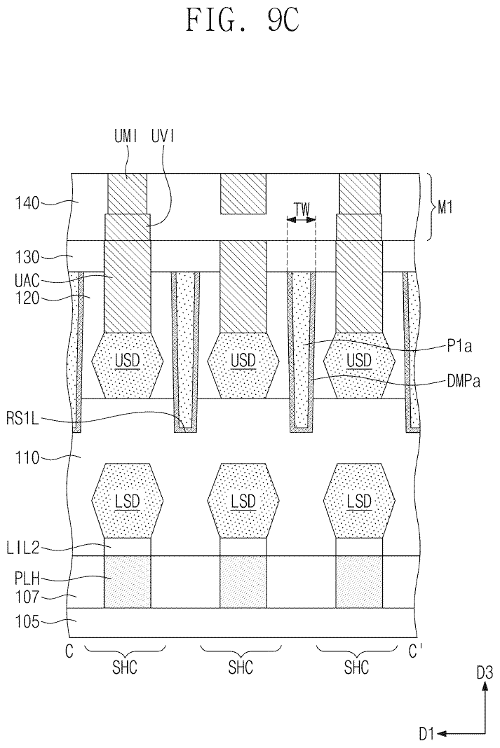

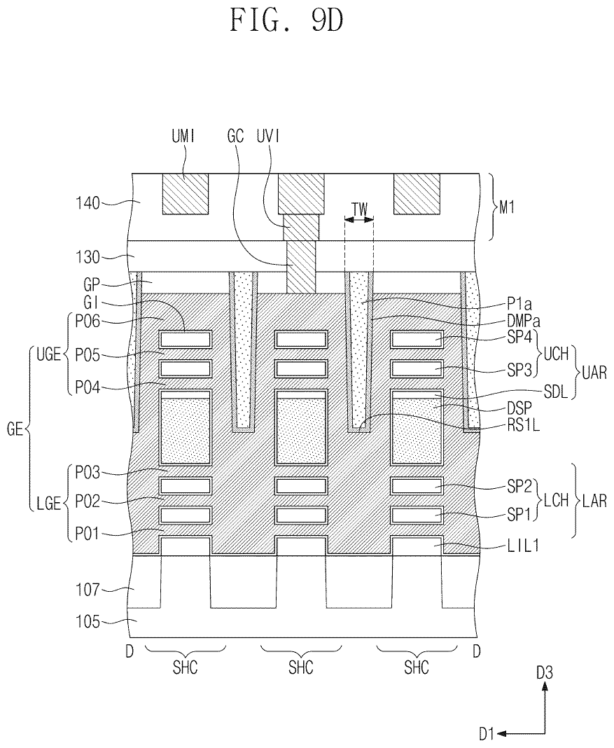

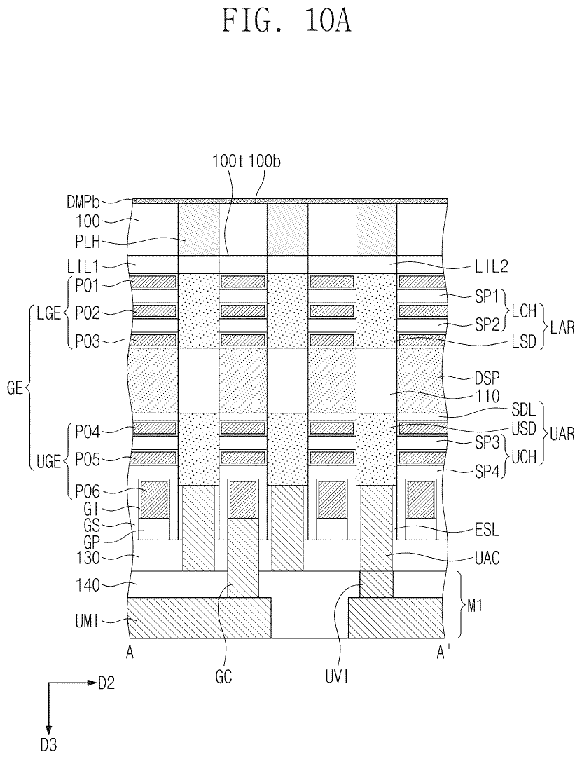

Referring to FIGS. 9A, 9B, 9C, and 9D, a first preliminary liner layer DMPa and a first preliminary portion P1a may be formed inside the first recesses RS1. Forming the first preliminary liner layer DMPa and the first preliminary portion P1a may include forming the first preliminary liner layer DMPa on the surface of the semiconductor substrate 105, forming an insulating material in the first recesses RS1 on the first preliminary liner layer DMPa, and performing a planarization process on the insulating material. The first preliminary liner layer DMPa may be formed with a uniform thickness on the entire surface of the semiconductor substrate 105. The insulating material may fill the first recesses RS1. Through the planarization process, an upper surface of the first preliminary portion P1a may be coplanar with upper surfaces of the second interlayer insulating layer 120 and the gate capping patterns GP.

A third interlayer insulating layer 130 may be formed on the second interlayer insulating layer 120, and upper active contacts UAC may be formed through the third interlayer insulating layer 130 and may be connected to the upper source/drain patterns USD, respectively. Additionally, a gate contact GC may be formed through the third interlayer insulating layer 130 and the gate capping patterns GP and may be connected to the gate electrodes GE. For example, the upper active contacts UAC and gate contact GC may be formed a metal including at least one of copper (Cu), aluminum (Al), ruthenium (Ru), cobalt (Co), tungsten (W), or molybdenum (Mo).

A fourth interlayer insulating layer 140 may be formed to cover the third interlayer insulating layer 130. A first metal layer M1 including upper interconnections UM1 may be formed in the fourth interlayer insulating layer 140. Upper vias UV1 may be formed in the first metal layer M1 to electrically connect the upper interconnections UM1, the gate contact GC, and the upper active contacts UAC. A BEOL layer including a plurality of metal layers may be formed on the first metal layer M1.

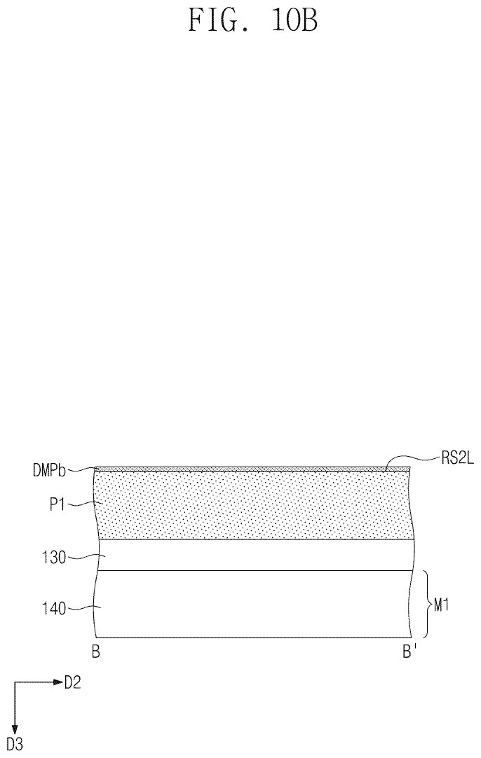

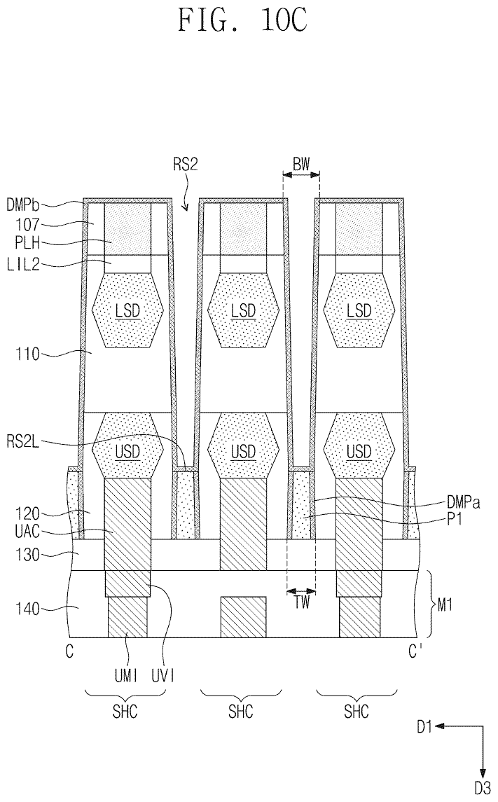

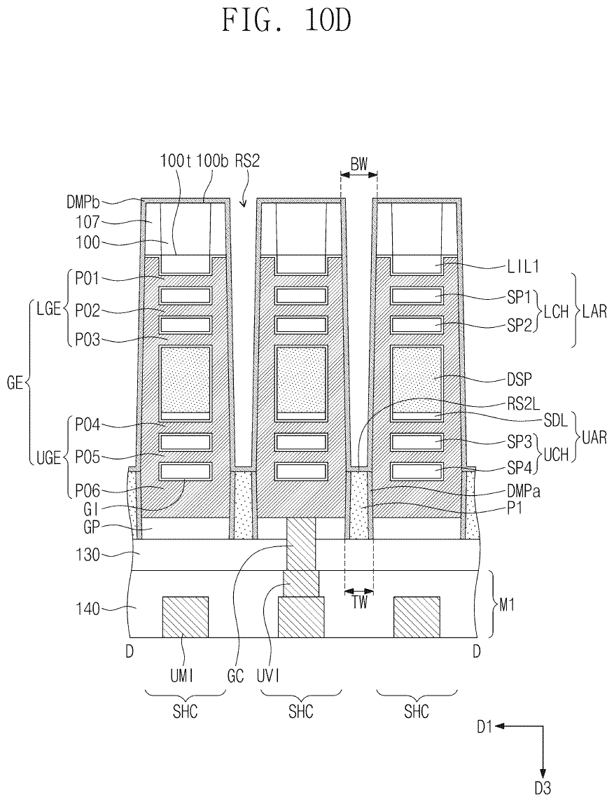

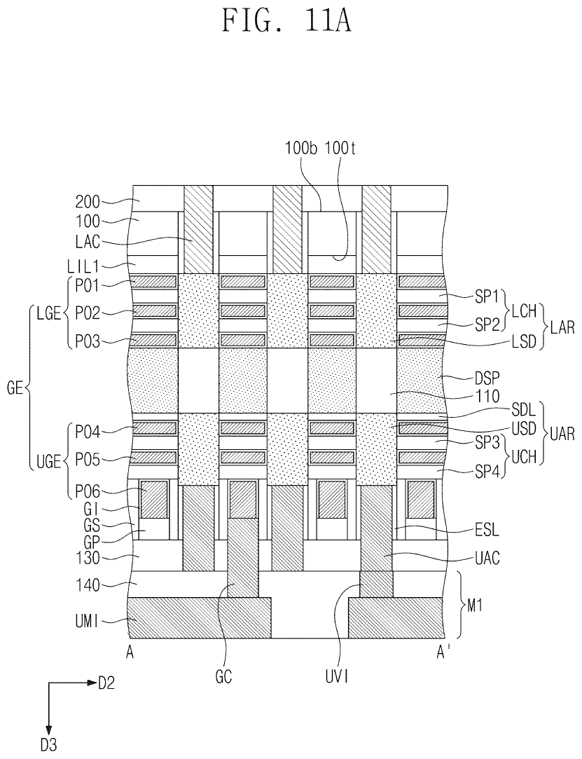

Referring to FIGS. 10A, 10B, 10C, and 10D, the semiconductor substrate 105 may be turned over to expose a back surface of the semiconductor substrate 105. A planarization process may be performed on the back surface of the semiconductor substrate 105 at least until the sacrificial contact patterns PLH and the device isolation layer 107 are exposed. A height of the semiconductor substrate 105 may be reduced through the planarization process. The semiconductor substrate 105 may be replaced with a substrate 100. The substrate 100 may be an insulating substrate including a silicon-based insulating material (e.g., silicon oxide and/or silicon nitride).

Second recesses RS2 may be formed between the single height cells SHC. The second recesses RS2 may be formed through an etching process using a mask pattern on the second surface 100b of the substrate 100. When viewed in a plan view, the second recesses RS2 may be spaced apart from each other in the first direction D1, and each of the second recesses RS2 may extend in the second direction D2. Each of the second recesses RS2 may have a lower width BW from an upper end thereof in the first direction D1. For example, each of the second recesses RS2 may vertically overlap the first recesses RS1 described with reference to FIGS. 8A to 8D, and the lower width BW may be greater than an upper width TW.

The second recesses RS2 may extend through the device isolation layer 107 and the first interlayer insulating layer 110 into the second interlayer insulating layer 120 or the gate electrodes GE. For example, the second recesses RS2 may extend in the third direction D3 at least until a portion of the first preliminary liner layer DMPa and a portion of the first preliminary portion P1a are removed. The first portion P1 may be formed and the first portion P1 may be exposed to the outside through the second recesses RS2.

A second preliminary liner layer DMPb may be formed on the second surface 100b of the substrate 100. The second preliminary liner layer DMPb may be disposed on the inner walls and bottom surfaces RS2L of the second recesses RS2. The second preliminary liner layer DMPb may cover the inner walls and bottom surfaces RS2L of the second recesses RS2 with a uniform thickness. The second preliminary liner layer DMPb may be in contact with the first portion P1 and the first preliminary liner layer DMPa in the second recesses RS2.

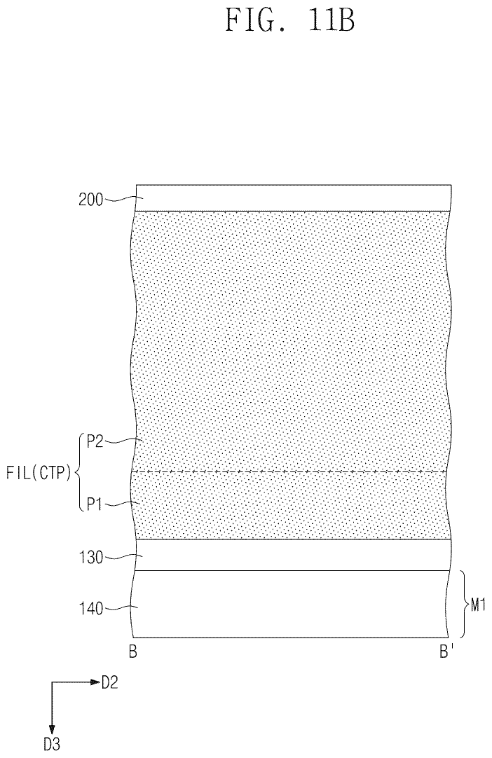

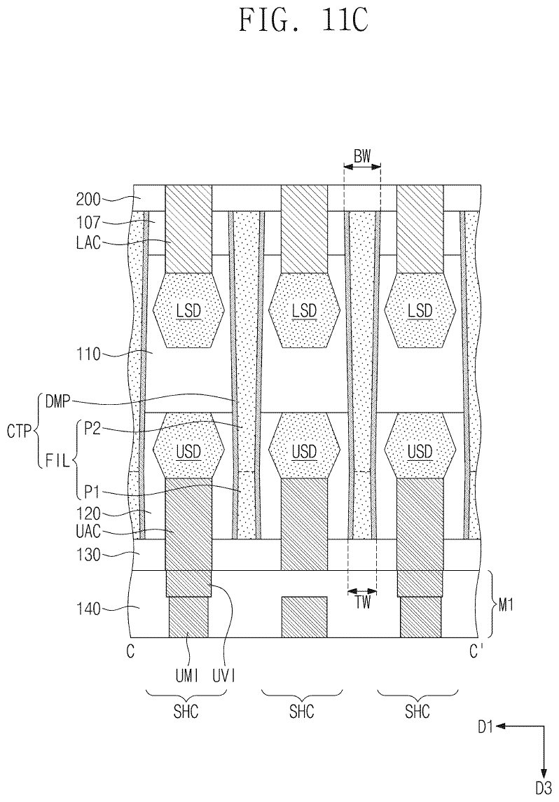

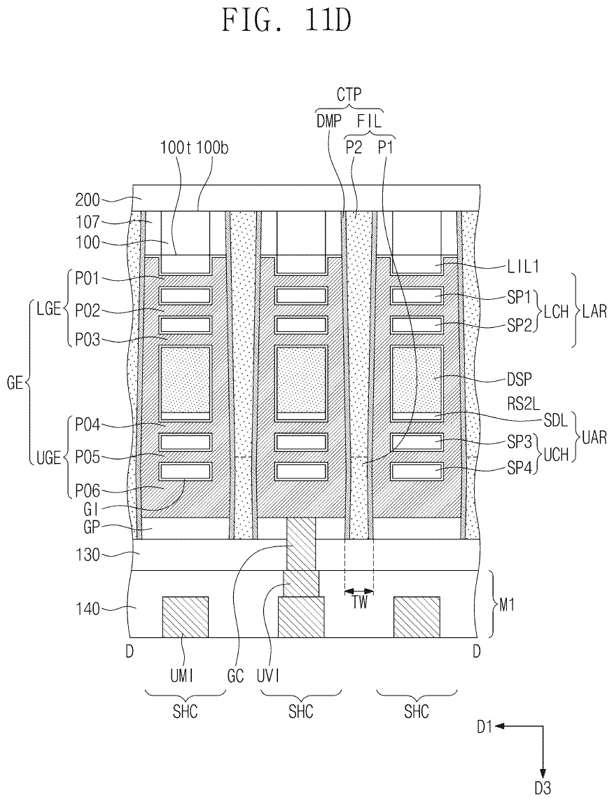

Referring to FIGS. 11A, 11B, 11C, and 11D, an etch-back process may be performed on the second preliminary liner layer DMPb. The second preliminary liner layer DMPb on the second surface 100b of the substrate 100 may be removed through the etch-back process. Additionally, a portion of the second preliminary liner layer DMPb on the bottom surfaces RS2L of the second recesses RS2 may also be removed. As a result, the second preliminary liner layer DMPb may be disposed only on the inner walls of the second recesses RS2, and the first portion P1 may be exposed again. The first preliminary liner layer DMPa and the second preliminary liner layer DMPb may form a liner layer DMP disposed on sidewalls of a buried insulating layer FIL, which will be described later.

After the liner layer DMP is formed, a second portion P2 may be formed in the second recesses RS2. Forming the second portion P2 may include forming an insulating material in the second recesses RS2. The insulating material of the second portion P2 may be formed in a single process or by multiple processes. The second recesses RS2 may be filled by the second portion P2. A planarization process may be performed on the insulating material. The planarization process may proceed at least until the second surface 100b of the substrate 100 and the device isolation layer 107 are exposed. The first portion Pl and the second portion P2 may be in contact with each other in various forms as described with reference to FIGS. 5A to 5C. A buried insulating layer FIL may be formed including the first portion P1 and the second portion P2, which may be in contact with each other, and gate cutting patterns CTP including the buried insulating layer FIL and the liner layer DMP may be formed.

A first lower interlayer insulating layer 200 may be formed on the second surface 100b of the substrate 100. The first lower interlayer insulating layer 200 may be disposed on the device isolation layer 107 and the second portion P2 of the buried insulating layer FIL. For example, the first lower interlayer insulating layer 200 may cover the device isolation layer 107 and the second portion P2 of the buried insulating layer FIL.

The first lower interlayer insulating layer 200 may be patterned to expose the sacrificial contact patterns PLH. The exposed sacrificial contact patterns PLH may be replaced with lower active contacts LAC. For example, the sacrificial contact patterns PLH may be selectively removed. An etching process may be performed in a space where the sacrificial contact patterns PLH have been removed, thereby exposing the lower source/drain patterns LSD. Lower active contacts LAC connected to each of the exposed lower source/drain patterns LSD may be formed. The lower active contacts LAC may be formed using a self-alignment method using sacrificial contact patterns PLH, but are not limited thereto.

Referring again to FIGS. 4A, 4B, 4C, and 4D, a second lower interlayer insulating layer 210 may be formed below the first lower interlayer insulating layer 200. A backside metal layer BSM may be formed in the second lower interlayer insulating layer 210. The backside metal layer BSM may include lower interconnections LMI. Lower vias LVI that electrically connect the lower active contacts LAC and lower interconnections LMI may be formed in the backside metal layer BSM. A plurality of backside metal layers may be formed on the backside metal layer BSM. For example, the plurality of backside metal layers may include a power transmission network layer. The power transmission network layer may include a wiring network for applying source voltage and/or drain voltage to the backside metal layer BSM.

A method of manufacturing a three-dimensional semiconductor device according to embodiments of the inventive concept may include forming the first portion P1 and the second portion P2 of the gate cutting pattern CTP using different processes. For example, the first portion P1 of the gate cutting pattern CTP may be formed on the first surface 100t of the substrate 100, and the second portion P2 may be formed on the second surface 100b of the substrate 100. Accordingly, the insulating material may be filled without voids in the gate cutting pattern CTP with a high aspect ratio. Additionally, the sizes of the recesses RS1 and RS2 for forming the first portion P1 and the second portion P2 may be reduced. Accordingly, electrical characteristics and integration of a three-dimensional semiconductor device may be improved.

According to embodiments of the inventive concept, the gate cutting pattern may include the first portion formed on the front surface of the substrate and the second portion formed on the back surface of the substrate. That is, as the first portion and the second portion are formed through different processes, the insulating material may be easily filled without voids in the gate cutting pattern with the large aspect ratio. Additionally, as the gate cutting pattern may be formed through multiple processes, the sizes of the recesses for forming the first portion and the second portion may be reduced. Accordingly, integration the electrical characteristics and reliability of a three-dimensional semiconductor device may be improved.

While embodiments are described above, a person skilled in the art may understand that many modifications and variations are made without departing from the spirit and scope of the inventive concept defined in the following claims. Accordingly, example embodiments of the inventive concept should be considered in all respects as illustrative and not restrictive, with the spirit and scope of the inventive concept being indicated by the appended claims.

What is claimed is:

1. A three-dimensional semiconductor device comprising:
a first active region on a substrate, the first active region including a lower channel pattern and lower source/drain patterns connected to the lower channel pattern;
a second active region on the first active region, the second active region including an upper channel pattern and an upper source/drain pattern connected to the upper channel pattern;
a gate electrode on the lower channel pattern and the upper channel pattern; and
a gate cutting pattern penetrating the gate electrode, and
wherein the gate cutting pattern has a middle width between an upper surface and a lower surface thereof that is less than an upper width of the gate cutting pattern and a lower width of the gate cutting pattern.

2. The three-dimensional semiconductor device of claim 1, wherein the gate electrode extends in a first direction, and
wherein the gate cutting pattern extends in a second direction intersecting the first direction.

3. The three-dimensional semiconductor device of claim 1, wherein the upper width is a width at the upper surface of the gate cutting pattern and the lower width is a width at the lower surface of the gate cutting pattern, and
wherein the upper width is less than the lower width.

4. The three-dimensional semiconductor device of claim 1, wherein the lower surface of the gate cutting pattern is coplanar with a lower surface of the substrate.

5. The three-dimensional semiconductor device of claim 1, wherein the gate cutting pattern includes a buried insulating layer and a liner layer on a sidewall of the buried insulating layer.

6. The three-dimensional semiconductor device of claim 1, wherein a vertical length of the gate cutting pattern is greater than a vertical length of the gate electrode.

7. The three-dimensional semiconductor device of claim 1, wherein each of the upper channel pattern and the lower channel pattern includes a plurality of semiconductor patterns spaced apart from each other, and
wherein the gate electrode surrounds the plurality of semiconductor patterns.

8. A three-dimensional semiconductor device comprising:
a first active region on a substrate, the first active region including a lower channel pattern and lower source/drain patterns connected to the lower channel pattern;
a second active region on the first active region, the second active region including an upper channel pattern and an upper source/drain pattern connected to the upper channel pattern;
a gate electrode disposed on the lower channel pattern and the upper channel pattern and extending in a first direction; and
a gate cutting pattern penetrating the gate electrode,
wherein the gate cutting pattern includes:
a first portion adjacent to the second active region; and
a second portion adjacent to the first active region, and
wherein each of the first portion and the second portion has a width that decreases as the first and second portions are adjacent to each other.

9. The three-dimensional semiconductor device of claim 8, wherein the gate cutting pattern extends in a second direction intersecting the first direction,
wherein the first portion has a first central axis along the first direction, and
wherein the second portion has a second central axis along the first direction.

10. The three-dimensional semiconductor device of claim 9, wherein the first central axis and the second central axis are aligned with each other.

11. The three-dimensional semiconductor device of claim 9, wherein the first central axis and the second central axis are spaced apart from each other.

12. The three-dimensional semiconductor device of claim 8, wherein the gate cutting pattern has a step surface between a sidewall of the first portion and a sidewall of the second portion.

13. The three-dimensional semiconductor device of claim 12, wherein the gate cutting pattern includes a liner layer on the sidewall of the first portion, the sidewall of the second portion, and the step surface.

14. The three-dimensional semiconductor device of claim 8, wherein the gate cutting pattern has an upper width at an upper surface thereof and a lower width at a lower surface thereof, and wherein the upper width and the lower width are different from each other.

15. The three-dimensional semiconductor device of claim 8, wherein a middle width of the gate cutting pattern is a minimum width at an interface where the first portion and the second portion are in contact with each other.

16. A three-dimensional semiconductor device comprising:
a first active region on a substrate, the first active region including a lower channel pattern and a lower source/drain pattern connected to the lower channel pattern;
a second active region on the first active region, the second active region including an upper channel pattern and an upper source/drain pattern connected to the upper channel pattern;
a lower active contact connected to the lower source/drain pattern;
an upper active contact connected to the upper source/drain pattern;
a gate electrode disposed on the lower channel pattern and the upper channel pattern and extending in a first direction;
a gate contact connected to the gate electrode; and
a gate cutting pattern extending in a second direction intersecting the first direction and penetrating the gate electrode,
wherein the gate cutting pattern includes a first portion and a second portion below the first portion, and
wherein the gate cutting pattern has a middle width at an interface where the first portion and the second portion are in contact with each other that is less than an upper width of the first portion of the gate cutting pattern and a lower width of second portion of the gate cutting pattern.

17. The three-dimensional semiconductor device of claim 16, wherein the first portion and the second portion include the same insulating material, and
wherein a central axis of the first portion and a central axis of the second portion are spaced apart from each other.

18. The three-dimensional semiconductor device of claim 16, wherein the upper width is a width at an upper surface of the gate cutting pattern and the lower width is a width at a lower surface of the gate cutting pattern, and
wherein the upper width is less than the lower width.

19. The three-dimensional semiconductor device of claim 16, wherein a minimum width of the first portion and a minimum width of the second portion are different from each other.

20. The three-dimensional semiconductor device of claim 16, wherein an upper surface of the gate cutting pattern is higher than an upper surface of the gate electrode, and
wherein a lower surface of the gate cutting pattern is lower than a lower surface of the gate electrode.
